(19) United States
(12) Patent Application Publication
(10) Pub. No.: US 2015/0318146 A1
(43) Pub. Date: Nov. 5, 2015

(54) SYSTEM AND METHOD FOR TREATING SUBSTRATE

(71) Applicant: SEMES CO., LTD., Cheonan-si (KR)

(72) Inventor: Je Ho KIM, Cheonan-si (KR)

(21) Appl. No.: 14/687,638

(22) Filed: Apr. 15, 2015

(30) Foreign Application Priority Data
Apr. 30, 2014 (KR) 10-2014-0052699

(51) Int. Cl. H01J 37/32; C23C 16/26; C23C 16/458; C23C 16/50; C23C 16/46

(52) U.S. Cl. CPC H01J 37/3244; C23C 16/50; C23C 16/46; C23C 16/458; C23C 16/463; C23C 16/26; H01J 37/32009; H01J 37/32715

(57) ABSTRACT

Provided are a system and a method for treating a substrate. The substrate treating system may include a process chamber including a body with an open top and a dielectric window hermetically sealing the top of the body from an outside, a supporting unit provided in the process chamber to support a substrate, a gas-supplying unit supplying a process gas into the process chamber, a plasma source provided outside the process chamber to generate plasma from the process gas supplied into the process chamber, and a heating unit heating the dielectric window. The heating unit may include a heater and a thermally conductive layer provided on one of surfaces of the dielectric window.

### CROSS-REFERENCE TO RELATED APPLICATIONS

This U.S. non-provisional patent application claims priority under 35 U.S.C. §119 to Korean Patent Application No. 10-2014-0052699, filed on Apr. 30, 2014, in the Korean Intellectual Property Office, the entire contents of which are hereby incorporated by reference.

### BACKGROUND OF THE INVENTION

Example embodiments of the inventive concept relate to a substrate treating system, and in particular, to a system of treating a substrate using plasma.

In general, a plasma treatment process is performed to fabricate a semiconductor device and a flat panel display. For example, plasma generated from a supplied gas may be used to treat a semiconductor substrate in a plasma treatment chamber, during a deposition, cleaning, ashing, or etching process. The plasma may be generated by one of various sources, such as a capacitively-coupled plasma (CCP) source and an inductively-coupled plasma (ICP) source.

In an ICP system, a dielectric window may be used as a transmission path of high frequency power.

The dielectric window is provided on a top wall of a process chamber, and an antenna may be provided on the dielectric window. The dielectric window may be heated by a heater during a plasma process. Typically, the heater may include a heating line made of a metallic material. In the case where the heater is provided on the entire top region of the dielectric window, it is possible to heat the entire region of the dielectric window but this may lead to electromagnetic interference between an electromagnetic wave, which is incident from the antenna to the dielectric window, and the heating line. To avoid this technical issue, the heater may be typically provided on an edge region of the dielectric window, but this may lead to a difference in temperature between center and edge regions of the dielectric window.

### SUMMARY

Example embodiments of the inventive concept provide a substrate treating system configured to uniformly provide heat to an entire region of a dielectric window and a method of treating a substrate using the same.

Also, other example embodiments of the inventive concept provide a substrate treating system preventing heat provided to a dielectric window from being exhausted to an outside and a method of treating a substrate using the same.

Example embodiments of the inventive concept provide a substrate treating system.

According to example embodiments of the inventive concept, a substrate treating system may include a process chamber including a body with an open top and a dielectric window hermetically sealing the top of the body from an outside, a supporting unit provided in the process chamber to support a substrate, a gas-supplying unit supplying a process gas into the process chamber, a plasma source provided outside the process chamber to generate plasma from the process gas supplied into the process chamber, and a heating unit heating the dielectric window. The heating unit may include a heater and a thermally conductive layer provided on one of surfaces of the dielectric window.

In example embodiments, the thermally conductive layer may be provided on a top surface of the dielectric window.

In example embodiments, the heating unit may further include an insulating layer provided on a top surface of the thermally conductive layer.

In example embodiments, the thermally conductive layer may be formed of a material whose thermal conductivity is higher than that of the dielectric window.

In example embodiments, the thermally conductive layer may be formed of a material whose thermal conductivity is higher than that of the dielectric window and the insulating layer may be formed of a material whose thermal conductivity is lower than that of the thermally conductive layer.

In example embodiments, the heater may be disposed to heat an edge region of the dielectric window.

In example embodiments, the plasma source may be provided on the dielectric window.

In example embodiments, the plasma source may include an antenna, and the substrate treating system may further include an antenna room provided on the process chamber to contain the antenna, and a cooling member supplying a cooling gas into the antenna room.

In example embodiments, the thermally conductive layer may include a graphene-containing material.

In example embodiments, the insulating layer may include sodium silicate.

Example embodiments of the inventive concept provide a method of treating a substrate.

According to example embodiments of the inventive concept, a method of treating a substrate may include supplying a process gas into a process chamber with a top-open body and a dielectric window, applying an electric power to an antenna provided outside the process chamber to generate plasma from the process gas in the process chamber, and then treating a substrate with the plasma. The method may further include heating the dielectric window, before or during the treating of the substrate, and the heating of the dielectric window may be performed using a heat energy, which is generated by a heater and is supplied to an edge portion of the dielectric window from the heater, and a fraction of which is transmitted to an entire region of the dielectric window through a thermally conductive layer in contact with the dielectric window.

In example embodiments, the thermally conductive layer may be provided on a top surface of the dielectric window, and the heating unit may further include an insulating layer provided on a top surface of the thermally conductive layer.

In example embodiments, the thermally conductive layer may be formed of a material whose thermal conductivity is higher than that of the dielectric window.

In example embodiments, the thermally conductive layer may be formed of a material whose thermal conductivity is higher than that of the dielectric window, and the insulating layer may be formed of a material whose thermal conductivity is lower than that of the thermally conductive layer.

In example embodiments, the heater may be provided to heat an edge region of the thermally conductive layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a substrate treating system according to example embodiments of the inventive concept.

FIG. 2 is a sectional view illustrating an example of a heating unit provided in the substrate treating system of FIG. 1.

FIG. 3 is a schematic diagram illustrating a flow of heat passing through a dielectric window, when the heating unit of FIG. 2 is configured not to have a thermally conductive layer and an insulating layer.

FIG. 4 is a schematic diagram exemplarily showing a heat flow, when the heating unit of FIG. 2 is used.

FIG. 5 is a sectional view illustrating another example of the heating unit provided in the substrate treating system of FIG. 1.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

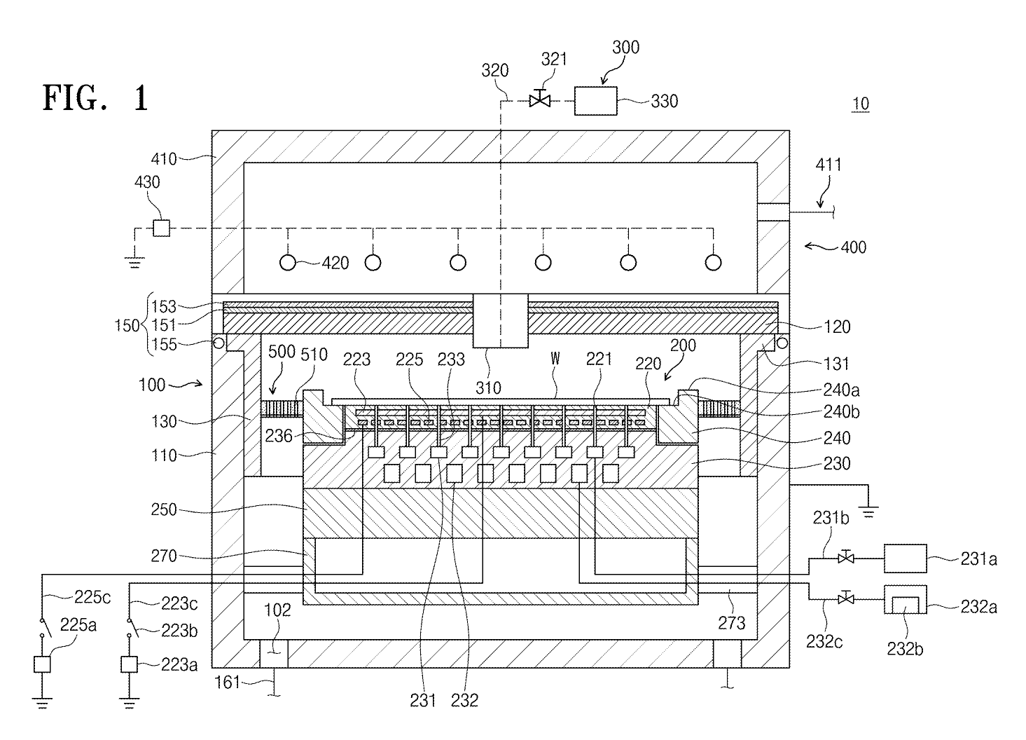

FIG. 1 is a sectional view illustrating a substrate treating system according to example embodiments of the inventive concept,

Referring to FIG. 1, a substrate treating system 10 may be configured to treat a substrate W using plasma. For example, the substrate treating system 10 may be configured to perform an etching process on the substrate W. The substrate treating system 10 may include a process chamber 100, a supporting unit 200, a gas-supplying unit 300, a plasma source 400, and a baffle unit 500.

The process chamber 100 may provide a space, in which a substrate treating process will be performed. The process chamber 100 may include a body 110, a dielectric window 120, a liner 130, and a heating unit 150.

The body 110 may have an internal space, which is provided therein, and whose top surface is open. The substrate treating process may be performed in the internal space of the body 110. The body 110 may be formed of a metallic material. The body 110 may be formed of, for example, an aluminum-containing material. The body 110 may be grounded. An exhausting hole 102 may be formed through a bottom surface of the body 110. The exhausting hole 102 may be connected to an exhausting line 161. A reaction side-product, which may be produced during the substrate treating process, and a remnant gas existing in the internal space of the body 110 may be exhausted to the outside through the exhausting line 161. As a result of the exhausting process, the body 110 may be decompressed to a specific pressure.

The liner 130 may be provided in the body 110. The liner 130 may be provided to define a space whose top and bottom surfaces are open. The liner 130 may be provided to have a cylindrical shape. The liner 130 may have a radius, which may correspond or equal to that of the internal space of the body 110. The liner 130 may be provided along an inner surface of the body 110. A support ring 131 may be provided at a top portion of the liner 130. The support ring 131 may be provided in the form of a ring-shaped plate and may protrude outward from an outer circumference of the liner 130. The supporting ring 131 may be disposed atop the body 110 to support the liner 130. The liner 130 may protect the inner side surface of the body 110 against damage. During excitation of a process gas, arc discharge may occur in the chamber 100. Such an arc discharge may lead to damage to neighboring devices. However, by virtue of the liner 130 provided on the inner side surface of the body 110, it is possible to prevent the inner side surface of the body 110 from being damaged by the arc discharge. Further, the liner 130 may prevent a pollutant material, which may be produced in the substrate treatment process, from being deposited on the inner side surface of the body 110. The liner 130 may be cost effective and easily replaceable when compared with the body 110. Thus, in the case where the liner 130 is damaged by an arc discharge, the liner 130 can be replaced with a new one by an operator.

The dielectric window 120 may be positioned on the body 110. The dielectric window 120 may have substantially the same radius as that of the body 110. The dielectric window 120 may be formed of or include aluminum oxide (Al₂O₃) or quartz. A surface of the dielectric window 120 may be coated with yttrium oxide (Y₂O₃).

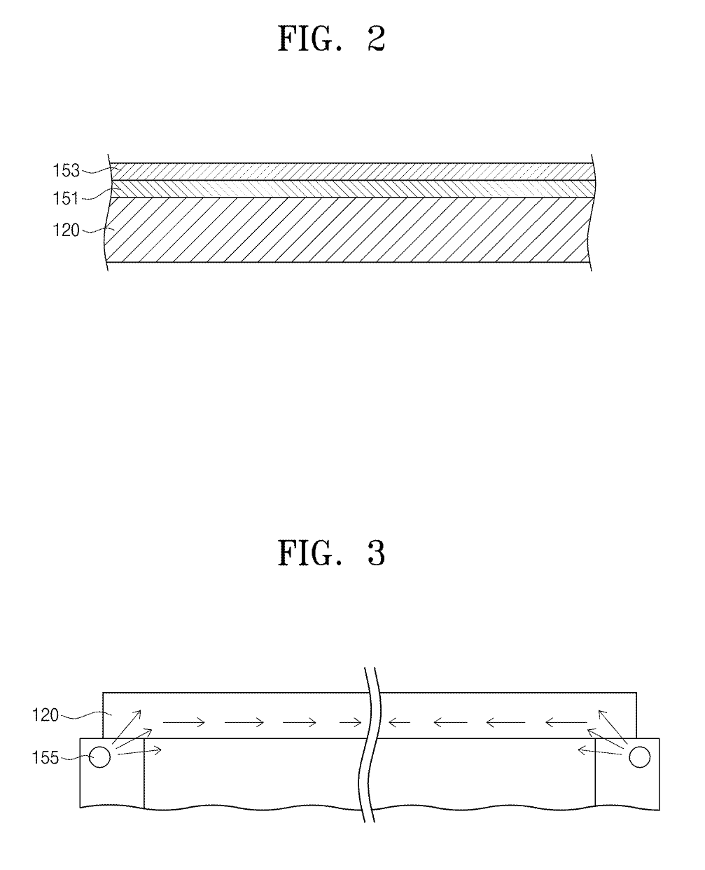

FIG. 2 is a sectional view illustrating an example of the heating unit 150 provided in the substrate treating system 10 of FIG. 1.

Referring to FIGS. 1 and 2, the heating unit 150 may include a thermally conductive layer 151, an insulating layer 153, and a heater 155. The heating unit 150 may be configured to heat the dielectric window 120. The heater 155 may be provided in the body 110 to be adjacent to an edge region of the dielectric window 120. The heater 155 may be configured to provide heat energy to the dielectric window 120.

The thermally conductive layer 151 may be provided on a surface of the dielectric window 120. In example embodiments, the thermally conductive layer 151 may be provided on a top surface of the dielectric window 120. The thermally conductive layer 151 may allow the heat energy provided to the edge region of the dielectric window 120 to be transmitted to a center region of the dielectric window 120. For example, the thermally conductive layer 151 may allow the entire region of the dielectric window 120 to have a uniform heat distribution. The thermally conductive layer 151 may be formed of or include a material whose thermal conductivity is higher than that of the dielectric window 120. In example embodiments, the thermally conductive layer 151 may include graphene.

The insulating layer 153 may be provided on a top surface of the thermally conductive layer 151. The insulating layer 153 may prevent heat flowing through the thermally conductive layer 151 from being exhausted toward a direction away from the dielectric window 120. The insulating layer 153 may be formed of or include a material, whose thermal conductivity is lower than that of the thermally conductive layer 151. Further, the insulating layer 153 may be formed of or include a material, whose thermal conductivity is lower than that of the dielectric window 120. In example embodiments, the insulating layer 153 may include sodium silicate.

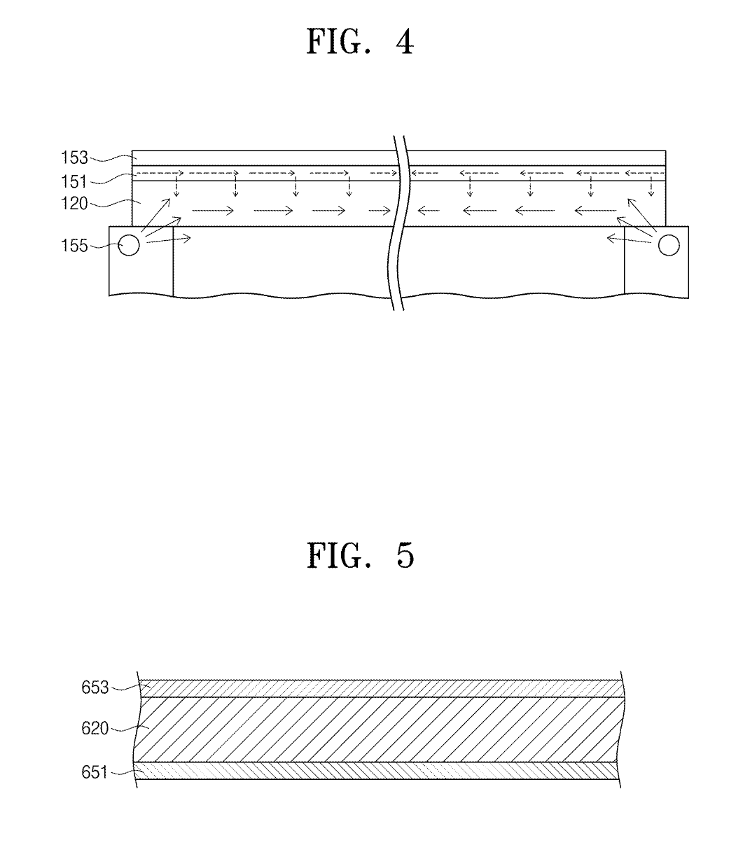

FIG. 3 is a schematic diagram illustrating a flow of heat passing through the dielectric window 120, when the heating unit 150 of FIG. 2 is configured not to have the thermally conductive layer 151 and the insulating layer 153, and FIG. 4 is a schematic diagram exemplarily showing a heat flow when the heating unit of FIG. 2 is used. In the drawings, the solid arrows represent a heat flow in the dielectric window 120, and the dashed arrows represent a heat flow in the thermally conductive layer 151. Each of the arrows is illustrated to have a length corresponding to an amount of heat energy.

Referring to FIG. 3, in the case where the thermally conductive layer 151 and the insulating layer 153 are not provided on the top surface of the dielectric window 120, heat energy may be transmitted from the heater 155 to the edge region of the dielectric window 120. A fraction of the heat energy may be transmitted to the center region of the dielectric window 120 through the dielectric window 120. In this case, there may be a relatively large temperature difference between the center and edge regions of the dielectric window 120.

By contrast, referring to FIG. 4, in the case where the thermally conductive layer 151 and the insulating layer 153 are provided on the top surface of the dielectric window 120, heat energy supplied from the heater 155 may be transmitted to the edge region of the dielectric window 120. A fraction of the heat energy supplied to the edge region of the dielectric window 120 may be transmitted to the center region of the dielectric window 120 through the dielectric window 120. Further, another fraction of the heat energy supplied to the edge region of the dielectric window 120 may be transmitted to the thermally conductive layer 151 and then may be transmitted to the center region of the dielectric window 120 through the thermally conductive layer 151. A fraction of the heat energy flowing through the thermally conductive layer 151 may be transmitted to the dielectric window 120 thereunder. The insulating layer 153 may prevent the heat energy supplied to the thermally conductive layer 151 from being exhausted from the thermally conductive layer 151, during the heat transmission process. As a result of such a heat transmission process, a temperature difference between the center and edge regions of the dielectric window 120 can be reduced.

FIG. 5 is a sectional view illustrating another example of the heating unit provided in the substrate treating system of FIG. 1. Referring to FIG. 5, a thermally conductive layer 651 of FIG. 5 may be provided on a bottom surface of a dielectric window 620, unlike the thermally conductive layer 151 of FIG. 2. An insulating layer 653 may be provided on a top surface of the dielectric window 620.

Referring back to FIG. 1, the supporting unit 200 may be provided in the body 110. The supporting unit 200 may be configured to support the substrate W. The supporting unit 200 may be configured to suction and hold the substrate W using an electrostatic force. Alternatively, the supporting unit 200 may be configured to hold the substrate W using other ways such as a mechanical clamping.

The supporting unit 200 may include an electrostatic chuck 210, an insulating plate 250, and a lower cover 270. The supporting unit 200 may be provided in the process chamber 100 to be spaced apart upward from the bottom surface of the body 110.

The electrostatic chuck 210 may include a dielectric plate 220, a lower electrode 223, a heater 225, a supporting plate 230, and a focus ring 240.

The dielectric plate 220 may be provided atop the electrostatic chuck 210. The dielectric plate 220 may be shaped like a circular disk and may be formed of a dielectric material. The substrate W may be disposed on a top surface of the dielectric plate 220. The top surface of the dielectric plate 220 may have a radius smaller than that of the substrate W. Accordingly, an edge region of the substrate W may be positioned outside the dielectric plate 220. A first supplying conduit 221 may be provided in the dielectric plate 220. The first supplying conduit 221 may be provided to extend from the top surface of the dielectric plate 220 to the bottom surface. In example embodiments, a plurality of first supplying conduits 221 may be provided spaced apart from each other and may be used as pathways for supplying a heat transfer medium toward the bottom surface of the substrate W.

The lower electrode 223 and the heater 225 may be buried in the dielectric plate 220. The lower electrode 223 may be positioned on the heater 225. The lower electrode 223 may be electrically connected to a first lower power 223a. The first lower power 223a may include a DC power. A switch 223b may be installed between the lower electrode 223 and the first lower power 223a. The lower electrode 223 may be electrically connected or disconnected to the first lower power 223a by turning the switch 223b on or off. For example, if the switch 223b is turned on, a DC current may be applied to the lower electrode 223. Due to a current applied to the lower electrode 223, an electrostatic force may be generated between the lower electrode 223 and the substrate W, and as a result, the substrate W may be fastened to the dielectric plate 220.

The heater 225 may be electrically connected to a second lower power 225a. The heater 225 may generate heat using the current applied to the second lower power 225a. The generated heat may be transmitted to the substrate W through the dielectric plate 220. For example, the heat generated by the heater 225 may allow the substrate W to be at a specific temperature. The heater 225 may include at least one spiral coil.

The supporting plate 230 may be provided below the dielectric plate 220. The bottom surface of the dielectric plate 220 may be attached to a top surface of the supporting plate 230 by an adhesive layer 236. The supporting plate 230 may be formed of an aluminum-containing material. The top surface of the supporting plate 230 may be higher at a center region thereof than at an edge region thereof, thereby having a staircase structure. The center region of the top surface of the supporting plate 230 may have substantially the same or similar area as that of the bottom surface of the dielectric plate 220 and may be adhered to the bottom surface of the dielectric plate 220. A first circulation conduit 231, a second circulation conduit 232, and a second supplying conduit 233 may be formed in the supporting plate 230.

The first circulation conduit 231 may serve as a pathway, through which a heat transfer medium is circulated. The first circulation conduit 231 may be a spiral structure provided in the supporting plate 230. Alternatively, the first circulation conduit 231 may be configured to include a plurality of ring-shaped conduits, which are formed in a concentric manner, and whose radii are different from each other. In certain embodiments, the conduits constituting the first circulation conduit 231 may be connected to each other. The conduits constituting the first circulation conduit 231 may be provided at the same level.

The second circulation conduit 232 may be used as a pathway, through which a coolant is circulated. The second circulation conduit 232 may be a spiral structure provided in the supporting plate 230. Alternatively, the second circulation conduit 232 may be configured to include a plurality of ring-shaped concentric conduits with radii different from each other. The second circulation conduit 232 may have a larger sectional area than that of the first circulation conduit 231. The conduits constituting the second circulation conduit 232 may be provided at substantially the same level. The second circulation conduit 232 may be provided below the first circulation conduit 231.

The second supplying conduit 233 may be extended upward from the first circulation conduit 231 to connect the first circulation conduit 231 to the top surface of the supporting plate 230. In certain embodiments, the second supplying conduit 233 may include a plurality of conduits, whose number is equal to that of the conduits constituting the first supplying conduit 221, and each of which connects one of the conduits constituting the first circulation conduit 231 to a corresponding one of the conduits constituting the first supplying conduit 221.

The first circulation conduit 231 may be connected to a heat transfer medium storage 231a through a heat transfer medium supplying line 231b. The heat transfer medium storage 231a may be configured to store the heat transfer medium. The heat transfer medium may include at least one of inactive or inert gases. In example embodiments, helium gas may be used as the heat transfer medium. As an example, the helium gas may be supplied to the first circulation conduit 231 through the heat transfer medium supplying line 231b and then may be supplied to the bottom surface of the substrate W through the second supplying conduit 233 and the first supplying conduit 221. The helium gas may serve as a medium for transmitting heat energy from plasma to the electrostatic chuck 210 through the substrate W.

The second circulation conduit 232 may be connected to a coolant storage 232a through a coolant supplying line 232c. The coolant storage 232a may be configured to store the coolant. A cooler 232b may be provided in the coolant storage 232a. The cooler 232b may be configured to quench the coolant to a predetermined temperature. Alternatively, the cooler 232b may be provided on the coolant supplying line 232c. The coolant supplied to the second circulation conduit 232 through the coolant supplying line 232c may be circulated through the second circulation conduit 232 to quench the supporting plate 230. If the supporting plate 230 is quenched, the dielectric plate 220 and the substrate W may also be quenched, and this may make it possible to maintain the temperature of the substrate W to a predetermined temperature.

The focus ring 240 may be provided on an edge region of the electrostatic chuck 210. The focus ring 240 may be shaped like a ring and may be provided along a circumference of the dielectric plate 220. The focus ring 240 may be provided to have a staircase structure; for example, an outer portion 240a of a top surface of the focus ring 240 may be positioned at a higher level than an inner portion 240b thereof. The inner portion 240b of the top surface of the focus ring 240 may be positioned at the same level as the top surface of the dielectric plate 220. The inner portion 240b of the top surface of the focus ring 240 may support the edge region of the substrate W positioned outside the dielectric plate 220. The outer portion 240a of the focus ring 240 may be provided to enclose the edge region of the substrate W. The focus ring 240 may be configured to concentrate plasma generated in the process chamber 100 on a region facing the substrate W.

The insulating plate 250 may be positioned below the supporting plate 230. The insulating plate 250 may be provided to have the same or similar sectional area as that of the supporting plate 230. The insulating plate 250 may be positioned between the supporting plate 230 and the lower cover 270. The insulating plate 250 may be formed of or include an insulating material to electrically separate the supporting plate 230 from the lower cover 270.

The lower cover 270 may be provided at a bottom portion of the supporting unit 200. The lower cover 270 may be provided at a position spaced apart upward from the bottom surface of the body 110. The lower cover 270 may be provided to define a top-open space therein. A top portion of the lower cover 270 may be covered with the insulating plate 250. In example embodiments, the lower cover 270 may be provided to have an outer radius which is substantially equivalent to that of the insulating plate 250. A lift pin module (not shown) may be provided in the space defined by the lower cover 270. For example, the lift pin module may be used to move the substrate W from an external transferring member to the electrostatic chuck 210, when the substrate W is loaded on the chamber 100.

The lower cover 270 may include a connection member 273. The connection member 273 may be provided to connect an outer side surface of the lower cover 270 to an inner side surface of the body 110. The connection member 273 may include a plurality of parts, which are provided spaced apart from each other and are connected to the outer side surface of the lower cover 270. The connection member 273 may be a structure, which is provided in the process chamber 100 to support the supporting unit 200. Further, the connection member 273 may be connected to the inner side surface of the body 110, and this may allow the lower cover 270 to be electrically grounded. A first power line 223c connected to the first lower power 223a, a second power line 225c connected to the second lower power 225a, the heat transfer medium supplying line 23 lb connected to the heat transfer medium storage 231a, and the coolant supplying line 232c connected to the coolant storage 232a may be extended into the lower cover 270 through an internal space of the connection member 273.

The gas supplying unit 300 may supply a process gas into the process chamber 100. The gas supplying unit 300 may include a gas supplying nozzle 310, a gas supplying line 320, and a gas storage 330. The gas supplying nozzle 310 may include an injection opening formed at a bottom thereof. The process gas may be supplied into the process chamber 100 through the injection opening. The gas supplying line 320 may connect the gas supplying nozzle 310 to the gas storage 330.

The gas supplying line 320 may supply the process gas stored in the gas storage 330 to the gas supplying nozzle 310. A valve 321 may be installed on the gas supplying line 320. The valve 321 may control an on/off operation of the gas supplying line 320 and thereby control a flow rate of the process gas to be supplied through the gas supplying line 320.

The plasma source 400 may be configured to cause the process gas in the chamber 100 to be excited into a plasma state. In example embodiments, an inductively-coupled plasma (ICP) source may be used as the plasma source 400. The plasma source 400 may include an antenna room 410, an antenna 420, and a plasma power 430. The plasma source 400 may be positioned on the dielectric window 120. The antenna room 410 may be provided on the process chamber 100. The antenna room 410 may be provided in the form of a bottom-open cylinder. The antenna room 410 may define an empty space therein. The antenna room 410 may be provided to have a diameter substantially equal to that of the process chamber 100.

A cooling member 411 may be positioned outside the antenna room 410. The cooling member 411 may supply a cooling gas to the antenna room 410.

The antenna 420 may be provided in the antenna room 410. The antenna 420 may be provided to have a spiral structure with a plurality of windings and may be coupled to the plasma power 430. The antenna 420 may be supplied with an electric power provided from the plasma power 430. The plasma power 430 may be positioned outside the process chamber 100. In the case where the electric power is applied to the antenna 420, an electromagnetic field may be generated in a treatment space of the process chamber 100. The process gas may be excited into a plasma state by the electromagnetic field.

A baffle 500 may be provided between the inner side surface of the body 110 and the supporting unit 200. The baffle 500 may be provided in the form of a circular ring. A plurality of through holes 510 may be formed through the baffle 500. The process gas supplied into the body 110 may be exhausted to the exhausting hole 102 through the through holes 510 of the baffle 500. Shapes of the baffle 500 and the through holes 510 may be variously changed to control a flow of the process gas.

According to example embodiments of the inventive concept, a substrate treating system may be configured to heat the entire region of a dielectric window, when a substrate treatment process is performed using plasma, and this makes it possible to improve process efficiency of the substrate treatment process.

According to example embodiments of the inventive concept, a substrate treating system may include a thermally conductive layer, which is provided on a top surface of the dielectric window to allow a heat energy supplied to the dielectric window to be uniformly distributed over the entire region of the dielectric window. The use of the thermally conductive layer allows a substrate treatment process to be performed with improved efficiency.

According to example embodiments of the inventive concept, a substrate treating system may include an insulating layer configured to prevent a heat energy supplied to the dielectric window from being exhausted to the outside and thereby to improve process efficiency of the substrate treatment process.

While example embodiments of the inventive concepts have been particularly shown and described, it will be understood by one of ordinary skill in the art that variations in form and detail may be made therein without departing from the spirit and scope of the attached claims.

1. A substrate treating system, comprising:
a process chamber including a body with an open top and a dielectric window hermetically sealing the top of the body from an outside;
a supporting unit provided in the process chamber to support a substrate;
a gas-supplying unit supplying a process gas into the process chamber;
a plasma source provided outside the process chamber to generate plasma from the process gas supplied into the process chamber; and
a heating unit heating the dielectric window,
wherein the heating unit comprises:
a heater; and
a thermally conductive layer provided on one of surfaces of the dielectric window.

2. The system of claim 1, wherein the thermally conductive layer is provided on a top surface of the dielectric window.

3. The system of claim 2, wherein the heating unit further comprises an insulating layer provided on a top surface of the thermally conductive layer.

4. The system of claim 1, wherein the thermally conductive layer is formed of a material whose thermal conductivity is higher than that of the dielectric window.

5. The system of claim 3, wherein the thermally conductive layer is formed of a material whose thermal conductivity is higher than that of the dielectric window and the insulating layer is formed of a material whose thermal conductivity is lower than that of the thermally conductive layer.

6. The system of claim 4, wherein the heater is disposed to heat an edge region of the dielectric window.

7. The system of claim 4, wherein the plasma source is provided on the dielectric window.

8. The system of claim 4, wherein the plasma source comprises an antenna, and the substrate treating system further comprises:
an antenna room provided on the process chamber to contain the antenna; and
a cooling member supplying a cooling gas into the antenna room.

9. The system of claim 4, wherein the thermally conductive layer comprises a graphene-containing material.

10. The system of claim 3 or 5, wherein the insulating layer comprises sodium silicate.

11. A method of treating a substrate, comprising supplying a process gas into a process chamber with a top-open body and a dielectric window, applying an electric power to an antenna provided outside the process chamber to generate plasma from the process gas in the process chamber, and then treating a substrate with the plasma,
wherein the method further comprises heating the dielectric window, before or during the treating of the substrate, and
the heating of the dielectric window is performed using a heat energy, which is generated by a heater and is supplied to an edge portion of the dielectric window from the heater, and a fraction of which is transmitted to an entire region of the dielectric window through a thermally conductive layer in contact with the dielectric window.

12. The method of claim 11, wherein the thermally conductive layer is provided on a top surface of the dielectric window, and the heating unit further comprises an insulating layer provided on a top surface of the thermally conductive layer.

13. The method of claim 10, wherein the thermally conductive layer is formed of a material whose thermal conductivity is higher than that of the dielectric window.

14. The method of claim 13, wherein the thermally conductive layer is formed of a material whose thermal conductivity is higher than that of the dielectric window, and the insulating layer is formed of a material whose thermal conductivity is lower than that of the thermally conductive layer.

15. The method of claim 11, wherein the heater is provided to heat an edge region of the thermally conductive layer.

16. The system of claim 2, wherein the thermally conductive layer is formed of a material whose thermal conductivity is higher than that of the dielectric window.

17. The system of claim 3, wherein the thermally conductive layer is formed of a material whose thermal conductivity is higher than that of the dielectric window.

18. The system of claim 5, wherein the insulating layer comprises sodium silicate.

19. The method of claim 11, wherein the thermally conductive layer is formed of a material whose thermal conductivity is higher than that of the dielectric window.

20. The method of claim 12, wherein the thermally conductive layer is formed of a material whose thermal conductivity is higher than that of the dielectric window.
